(19) United States
(12) Patent Application Publication
(10) Pub. No.: US 2017/0263584 A1
(43) Pub. Date: Sep. 14, 2017

(54) COLLET

(71) Applicant: LD MICRO PRECISION SDN BHD, Bayan Lepas, Pulau Pinang (MY)

(72) Inventors: SIAW LING LAI, BAYAN LEPAS (MY); KEAN LEE TAN, BAYAN LEPAS (MY)

(21) Appl. No.: 15/503,657

(22) PCT Filed: May 26, 2015
(86) PCT No.: PCT/MY2015/050036

§ 371 Date: Feb. 13, 2017

(30) Foreign Application Priority Data
Aug. 18, 2014 (MY) PI2014702292

(51) Int. Cl. H01L 23/00; B23K 3/08; H01L 21/67; H01L 21/683

(52) U.S. Cl. CPC H01L 24/75; H01L 21/6838; B23K 3/087; H01L 21/67144; B23K 2201/40

(57) ABSTRACT

A collet for attachment to distal portion (16) of a die-transporting shank (17), which comprises: a body (13) having a through hole (2) in its centre; said hole (2) consisting of three sections (3, 6, 7); first section (3) adjacent the proximal end (4) of the body (13), shaped to receive a protrusion on the shank distal portion (16); second section (6) adjacent the first section (3), linking the first section (3) to third section (7); said third section (7) opening to distal end (11) of the body (13); and an insert (14) having a through hole (10) in its centre, fitted into the third section (7); said insert hole (10) being smaller in diameter than that of the second section (6); distal portions of the body (13) and the insert (14) being of frusto-conical shape, having a flat-ended insert portion (12) extending beyond the distal end (11) of the body (13).

This invention relates to a collet for attachment to distal portion of a die-transporting shank, more specifically, to a collet for a more efficient transportation of dies.

### BACKGROUND OF THE INVENTION

Die-bonding is a process in which a die (or chip) is attached to a package or substrate. Said process, which is performed by a shank of a die-transporting tool, comprises steps of: separating the die from a sticky tape, e.g. Mylar, using an ejector pin (needle); picking up a die from a wafer by the shank using vacuum suction; holding the die firmly while transporting it to a spot on which solder paste has been deposited; and releasing the die onto the spot by deactivating the vacuum suction.

For preventing any detrimental impact on dies, a collet is attached to distal portion of the shank. Three materials are generally employed to fabricate a collet, namely carbide, polyimide-based plastics, and nitrile butadiene rubber (hereinafter referred to as NBR).

Due to hardness of carbide, a carbide collet is very difficult to fabricate. This kind of collet is shaped by grinding and electric discharge machining (EDM) processes which result in a very high fabrication cost. Furthermore, the hardness results in marks, scratches, or cracks, on surfaces of the dies.

A polyimide-based plastic, particularly one that is trademarked as Vespel, is a semisoft material which can easily be machined and fitted onto the shank. Despite these advantages, this plastic is a proprietary material, and is therefore more expensive compared to other materials.

NBR is mouldable at a comparatively low cost. However, this material has a relatively short lifespan. Also, it tends to be sticky to the dies, and contributes to missing dies or a loss in yield.

### SUMMARY OF THE INVENTION

According to the invention, the downsides are overcome and improvements are achieved by a collet for attachment to distal portion of a die-transporting shank, which comprises: a body having a through hole in its centre; said hole consisting of three sections; first section adjacent the proximal end of the body, shaped to receive a protrusion on the shank distal portion; second section adjacent the first section, linking the first section to third section; said third section opening to distal end of the body; and an insert having a through hole in its centre, fitted into the third section; said insert hole being smaller in diameter than that of the second section; distal portions of the body and the insert being of frusto-conical shape, having a flat-ended insert portion extending beyond the distal end of the body.

Preferably, the second section is circular.

Advantageously, the third section is circular.

Preferably, the insert is cylindrical.

Advantageously, distal end of the insert is circular, rectangular, or square.

Preferably, the body hole also consists of fourth section opening to the proximal end of the body, flared toward said proximal end to facilitate reception of the protrusion on the shank distal portion.

Advantageously, the first and the fourth sections are rectangular.

Preferably, the second section is smaller in diameter compared to the third section; edges at which the second and the third sections meet, forms a step which stops the insert from passing into the second section.

Advantageously, the body is made of rubber.

Preferably, the insert is made of resin or plastic which is anti-static, and harder than the body.

Advantageously, the insert is made of polyoxymethylene plastic.

The invention also provides a method for making a collet for attachment to distal portion of a die-transporting shank, which comprises steps of: making a plurality of collet blanks via die-casting; making a plurality of inserts using a milling machine; fitting the insert into a centre hole in distal end of the blank; and grinding the distal portions of the blank and the insert fitted in the hole, into frusto-conical shapes, having a flat-ended ground insert portion extending beyond distal end of the ground blank.

Preferably, the method also comprises a step of slicing the distal portions into a circular, rectangular, or square shape.

Advantageously, the die-casting comprises steps of: designing a mould of a plurality of collet blanks, said mould consisting of a male and a female units; heating a substrate sheet; compressing the sheet between the male and the female units; releasing the units and removing compressed sheet from the units; and deflecting the sheet to singulate the blanks off the sheet.

Preferably, the making of the inserts comprises steps: cutting a substrate sheet into a form of a plurality of inserts; drilling a centre hole for each of the inserts; and singulating the inserts off the sheet.

Advantageously, the blank is made of rubber.

Preferably, the insert is made of resin or plastic, which is anti-static and harder than the blank.

Advantageously, the insert is made of polyoxymethylene plastic.

### DESCRIPTION OF THE PREFERRED EMBODIMENT

The invention will now be described in greater detail, by way of example, with reference to the accompanying drawings, in which:

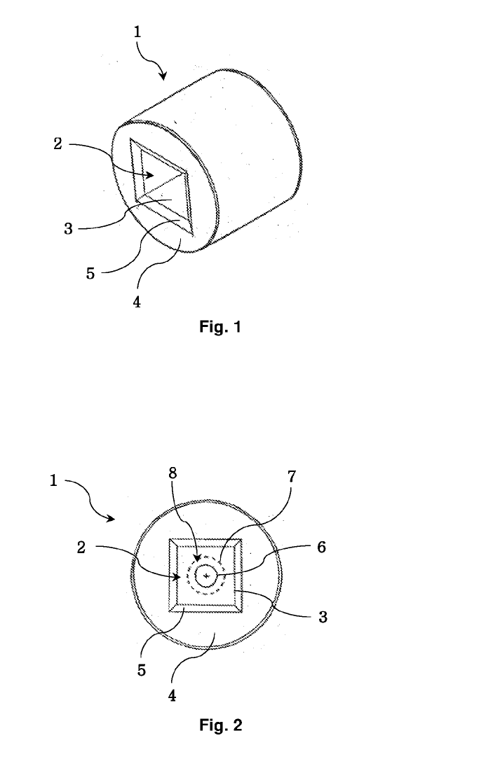

FIG. 1 is a perspective view of a collet blank according to the invention;

FIG. 2 is a top view of the blank;

FIG. 3 is, according to the invention, a perspective view of the blank and an insert prior to insertion into centre hole of the blank;

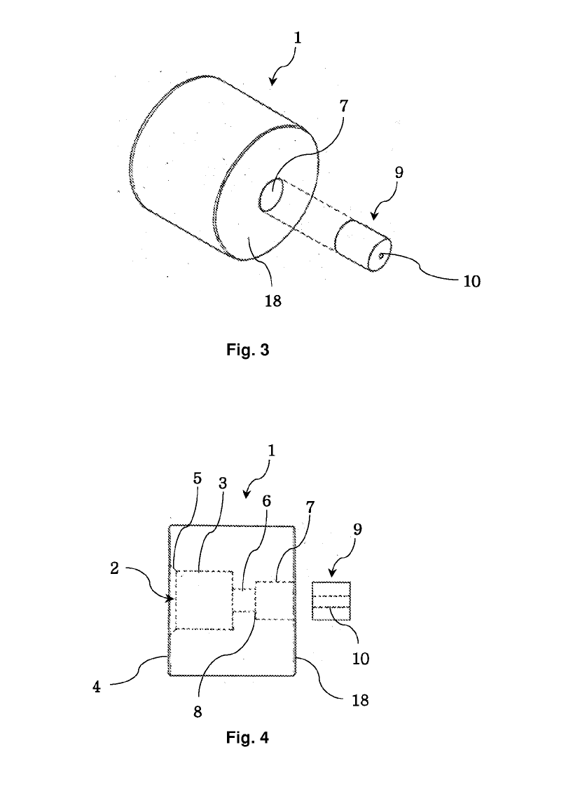

FIG. 4 is a side view of the blank and the insert;

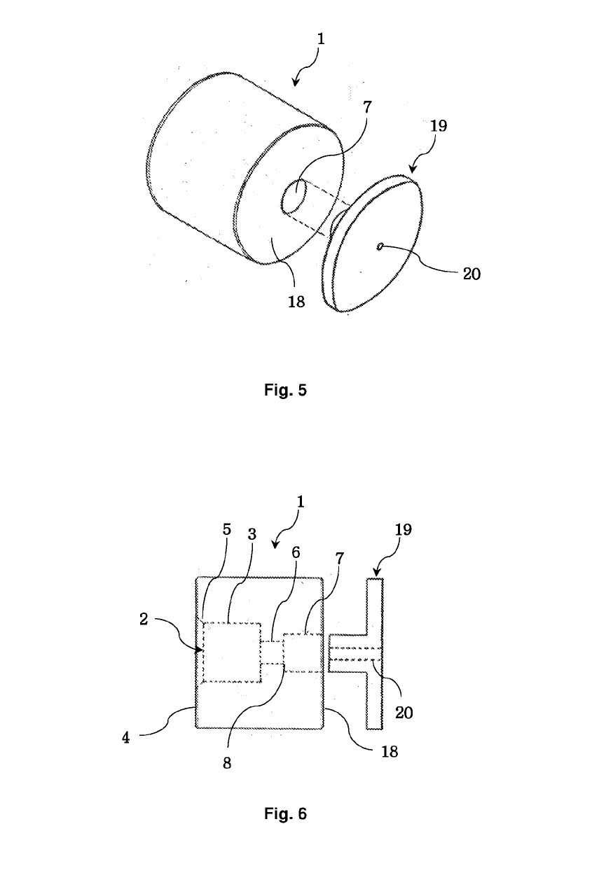

FIG. 5 is a perspective view of the blank and a flanged insert prior to insertion into the centre hole of the blank;

FIG. 6 is a side view of the blank and the flanged insert;

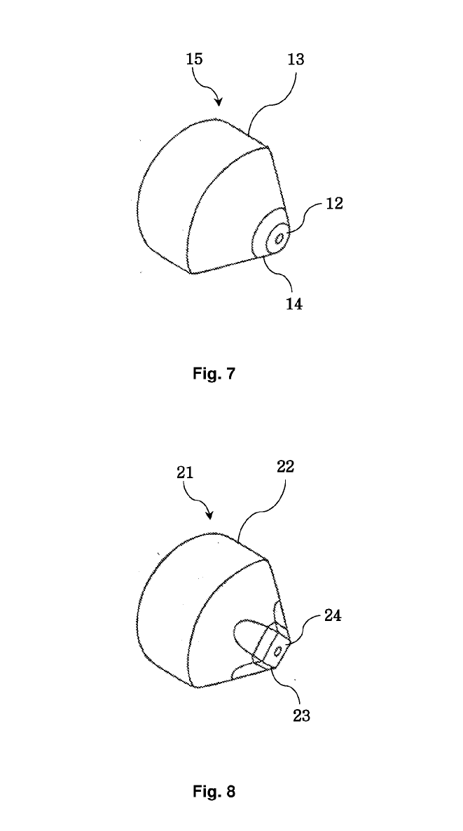

FIG. 7 a perspective view of one form of a collet according to the invention;

FIG. 8 a perspective view of another form of the collet; and

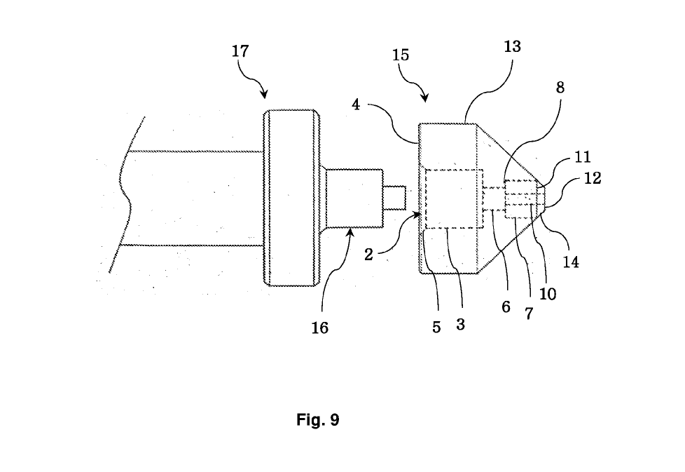

FIG. 9 is a side view of a die-transporting shank, and the blank and the insert having their distal end portions ground.

As shown in FIG. 1, the cylindrical collet blank 1 has a through hole 2 in its centre, and said hole 2 consists of a plurality of sections. First section 3 adjacent proximal end 4 of the blank 1, is rectangular, shaped to receive a protrusion on distal portion of a die-transporting shank. Second section 6 (as shown in FIG. 4) adjacent the first section 3, is circular, and links the first section 3 to third section 7 (as shown in FIG. 4). Said third section 7 is circular, and opens to distal end of the blank 1. Apart from that, the blank hole 2 also consists of a fourth section 5 which opens to the proximal end 4 of the blank and is flared toward said proximal end 4 to facilitate reception of the protrusion on the shank portion.

The collet blank 1 is made of rubber, via a die-casting process whose steps comprise: designing a mould of a plurality of collet blanks 1, said mould consisting of a male and a female units; heating a substrate sheet; compressing the sheet between the male and the female units; releasing the units and removing compressed sheet from the units; and deflecting the sheet to singulate the blanks 1 off the sheet.

As shown in FIG. 2, the top view shows shape of each section 3, 6, 7, 5 of the hole 2. The first 3 and the fourth 5 sections are rectangular, and the second 6 and the third 7 sections are circular. The second section 6 is smaller in diameter compared to the third section 7. Edges 8 at which the second 6 and the third 7 sections meet, forms a step which stops an insert from passing into the second section 6.

As shown in FIGS. 3 to 6, the insert can be cylindrical 9 or flanged 19 on its distal end. The insert which has a through hole 10, 20 in its centre, is fitted into the third section 7 of the hole 2. Diameter of the insert hole 10, 20, which can be as small as 0.085 mm, is smaller than diameter of the second section 6.

The insert 9, 19 is made of resin or plastic, e.g. polyoxymethylene plastic, which is anti-static and harder than the blank 1, using a milling machine. The process of making the insert 9, 19 comprises steps of: cutting a substrate sheet into a form of a plurality of inserts 9, 19; drilling a centre hole 10 for each of the inserts 9, 19; and singulating the inserts 9, 19 off the sheet.

As shown in FIG. 7, the collet 15 comprises: a body 13 and an insert 12 fitted in the hole 2 of the body 13. Distal portion of the body 13 and the insert 14 is of frusto-conical shape, wherein the flat-ended insert portion 12 extends beyond the distal end 11 of the body 13.

As shown in FIG. 8, the collet 21 is of the same configuration as FIG. 7, but distal portion of a body 22 and an insert 23 is sliced into a rectangular or square shape.

As shown in FIG. 9, ends of the body 13 and the insert 14 is of a frusto-conical shape which has a flat-ended insert portion 12 extending beyond the distal end 11 of the body 13. The shape is formed by subjecting distal portions of the blank 1 and the insert 9, 19 fitted in the third section 7 of the hole 2, to a grinding process. During use, the collet 15 is fitted onto distal portion 16 of the shank 17. The first 3, second 6, and fourth 5 sections accommodate a protrusion of the shank distal portion 16.

1.-18. (canceled)

19. A collet for attachment to distal portion of a die-transporting shank, comprising:
a body made of elastic material having a through hole in its center;
said hole consisting of three sections;
first section adjacent the proximal end of the body, shaped to receive a protrusion on the shank distal portion;
second section adjacent the first section, linking the first section to third section;
said third section opening to distal end of the body;
said second section is smaller in smaller in diameter compared to the first section and third section; and
an insert made of material which is harder than the body having at least one through hole, fitted into the third section;
said insert hole being smaller in diameter than that of the second section;
distal portions of the body and the insert being of frusto-conical shape, having a flat-ended insert portion extending beyond the distal end of the body;
wherein said edges at which the second and the third sections meet, forms a step within the through hole of the body which stops the insert from passing into the second section.

20. The collet as claimed in claim 19, wherein the second section is circular.

21. The collet as claimed in claim 20, wherein the third section is circular.

22. The collet as claimed in claim 21, wherein the insert is cylindrical.

23. The collet as claimed in claim 22, wherein distal end of the insert is circular, rectangular, or square.

24. The collet as claimed in claim 23, wherein the body hole also consists of fourth section opening to the proximal end of the body, flared toward said proximal end to facilitate reception of the protrusion on the shank distal portion.

25. The collet as claimed in claim 24, wherein the first and the fourth sections are rectangular.

26. The collet as claimed in claim 25, wherein the elastic material is rubber.

27. The collet as claimed in claim 26, wherein the insert is made of resin or plastic which is anti-static, and it is harder than the body.

28. The collet as claimed in claim 27, wherein the insert is made of polyoxymethylene plastic.
